(19) United States
(12) Patent Application Publication
(10) Pub. No.: US 2006/0280216 A1
(43) Pub. Date: Dec. 14, 2006

(54) Semiconductor laser-based spectrometer

(76) Inventor: Vijaysekhar Jayaraman, Goleta, CA (US)

Correspondence Address: Vijaysekhar Jayaraman;Praevium Research, Inc., 270 Coronado Drive, Goleta, CA, 93117, US

(21) Appl. No.: 11/447,655

(22) Filed: Jun. 6, 2006

Related U.S. Application Data
(60) Provisional application No. 60/687,993, filed on Jun. 7, 2005.

(51) Int. Cl. H01S 5/00

(52) U.S. Cl. 372/50.121; 372/50.124

(57) ABSTRACT

A semiconductor laser-based spectrometer according to the present invention includes a plurality of semiconductor lasers comprising a plurality of semiconductor gain medium compositions directly coupled to a large-core multi-mode fiber with no intervening optics. An output radiation from the multi-mode fiber is tunable by switching the drive current amongst the lasers, and by thermal tuning of each laser in the array. In combination with presentation to a sample, and means for detection of a diffuse reflectance or transmittance, this assembly functions as a compact, high signal to noise ratio, fast measurement spectrometer. In one preferred embodiment of this invention the plurality of semiconductor lasers consists of Fabry-Perot edge-emitting lasers arranged around the perimeter of a cylindrical submount with a substantially circular cross-section. In another preferred embodiment a linear array of Fabry-Perot edge-emitting lasers is directly coupled to a multi-mode fiber. In still another preferred embodiment, a two-dimensional array of vertical cavity surface-emitting lasers is directly coupled to a multi-mode optical fiber.

### CROSS-REFERENCES TO RELATED APPLICATIONS

This application is entitled to the benefit of Provisional Patent Application Ser. No. 60/687,993, filed 2005, Jun. 7.

### STATEMENT REGARDING FEDERALLY SPONSORED RESEARCH OR DEVELOPMENT

This invention was made under a government grant. The U.S. government may have rights in this invention.

### BACKGROUND

1. Field of the Invention

This invention relates generally to tunable sources, spectroscopy, and multi-wavelength laser arrays.

2. Description Prior Art

Spectroscopy refers to the use of multi-wavelength radiation to non-invasively probe a variety of samples to determine the composition, health, or function of those samples. Prior-art spectroscopy is done with filtered white light sources, as illustrated in the prior art FIG. 1. Here, a white light source 100 emits a broadband radiation 130, which is filtered with a tunable monochromator 110, comprising a rotating grating 114 and slit 118, to generate a narrowband radiation 150, which probes a sample 120. A diffuse reflected radiation 160 is then detected by an optical detector 140. By tuning the monochromator 110, it is possible to construct a spectrum of the reflected radiation 160, which provides non-invasive information about the sample 120.

Although it provides wide wavelength coverage, the prior-art white light spectrometer of FIG. 1 suffers from a number of limitations. First, the filtered white light source has weak signal to noise ratio. Second, the grating-based system has critical intra-system mechanical alignments, and contains moving parts, leading to a bulky and complex system with slow measurement times. Lastly, some applications, such as (B. Tromberg, N. Shah, R. Lanning, A. Cerussi, J. Espinoza, T. Pham, L. Svaasand, and J. Butler, “Non-Invasive In Vivo Characterization of Breast Tumors Using Photon Migration Spectroscopy,” Neoplasia, vol. 2, nos. 1-2, January-April 2000, pp. 26-40) employ frequency domain measurements, which are not presently possible with white light sources, since white light sources cannot be easily modulated at the required 100 Mhz to 3 Ghz rates.

One solution to these problems is to replace the white-light source with a tunable laser. This eliminates the grating, since the laser provides a source of tunable narrow-band radiation which requires no further filtering. However, prior art tunable semiconductor lasers, such as those described in (B. Mason, S. Lee, M. E. Heimbuch, and L. A. Coldren, “Directly Modulated Sampled Grating DBR Lasers for Long-Haul WDM Communication Systems,” IEEE Photonics Technology Letters, vol. 9, no. 5, Mar. 1997, pp. 377-379), are limited in tuning range to less than 100 nm, because of the fundamental gain-bandwidth limit of semiconductors. Most spectroscopic applications, such as near infrared spectroscopy from 1100-2400 nm, agricultural spectroscopy from 800-1700 nm, or tissue spectroscopy from 650-1000 nm, require several hundred nm bandwidth. This necessitates the use of multiple discrete semiconductor lasers to assemble a tunable source, as in (B. Tromberg, N. Shah, R. Lanning, A. Cerussi, J. Espinoza, T. Pham, L. Svaasand, and J. Butler, “Non-Invasive In Vivo Characterization of Breast Tumors Using Photon Migration Spectroscopy,” Neoplasia, vol. 2, nos. 1-2, January-April 2000, pp. 26-40). This again leads to a bulky and complex system, typically involving complex optical coupling components or multiple optical fibers.

From the foregoing, it is clear that what is required is a laser-based spectrometer that can employ semiconductor lasers in a compact configuration without complex optical components or semiconductor gain-bandwidth limitations.

### SUMMARY OF THE INVENTION

The present invention provides a plurality of semiconductor lasers comprising a plurality of semiconductor gain medium compositions coupled to a multi-mode optical fiber with no intervening optical components. These semiconductor lasers can be arranged in a linear array or two-dimensional array, where the spatial extent of the array radiation is smaller than the core of a large core multi-mode optical fiber. An output radiation of the multi-mode fiber is presented to a sample, and an optical detector detects a diffuse reflectance or transmittance. All of these components combine to create a compact laser-based spectrometer with fast measurement time, high speed modulation, wide wavelength range, and high signal to noise ratio.

In one preferred embodiment of this invention, the semiconductor lasers are Fabry-Perot edge-emitting lasers which provide high output power, wavelength flexibility, and efficient thermal tuning. The Fabry-Perot lasers are arranged around the perimeter of a nearly circular cross-section cylindrical submount, enabling efficient coupling to an optical fiber. In another preferred embodiment, the semiconductor lasers are vertical cavity lasers arranged in a 2-dimensional grid.

A further understanding of the nature and advantages of the present invention may be realized by reference to the remaining portions of the specifications and drawings.

### BRIEF DESCRIPTION OF THE DRAWINGS

FIG. 1 is a schematic representation of a prior art grating-based spectrometer.

FIG. 2 is a schematic representation of an end view of a preferred embodiment of the present invention.

FIG. 3 is a schematic representation of a cross-section A-A′ through a portion of FIG. 2.

FIG. 4 is a schematic representation of an experimental configuration used to test a linear 4-channel array coupled to a single large-core multi-mode fiber according to the present invention.

FIG. 5 is a spectrum of wavelength bands emitted by the 4-channel array of FIG. 4.

FIG. 6 is a schematic representation of a preferred embodiment of the present invention employing vertical cavity surface emitting lasers.

### REFERENCE NUMERALS IN DRAWINGS

100 White light source

110 Tunable monochromator

120 Sample in prior art spectrometer

130 Broadband radiation emitted by white light source

140 Optical detector in prior art spectrometer

150 Narrow band radiation emitted by prior art spectrometer

160 Diffuse reflectance from sample in prior art spectrometer

200 Edge-emitting lasers in spectrometer according to present invention

210 Multi-mode fiber core in spectrometer according present invention

220 Cylindrical submount in spectrometer according to present invention

250 Flex circuit in spectrometer according to present invention

260 Circuit board in spectrometer according to present invention

270 Radiation components from edge-emitting lasers in spectrometer according to present invention

280 Electrical connections in spectrometer according to present invention

290 Optical axis of cylindrical submount in spectrometer according to present invention

300 Radiation output from fiber core in spectrometer according to present invention

310 Sample in spectrometer according to present invention

320 Reflectance from sample in spectrometer according to present invention

330 Optical detector in spectrometer according to present invention

400 4-channel linear array according to present invention

410 positive probe

420 negative probe

430 Temperature-controlled stage

440 Plurality of radiation components from 4-channel linear array

450 1 mm core diameter fiber used to test 4-channel linear array

500 First wavelength band

510 Second wavelength band

520 Third wavelength band

530 Fourth wavelength band

600 Multi-mode fiber core in VCSEL-based spectrometer according to present invention

610 Plurality of radiation components emitted by VCSELs in spectrometer according to present invention

620 Plurality of VCSELs in spectrometer according to present invention

### DETAILED DESCRIPTION OF THE PREFERRED EMBODIMENTS

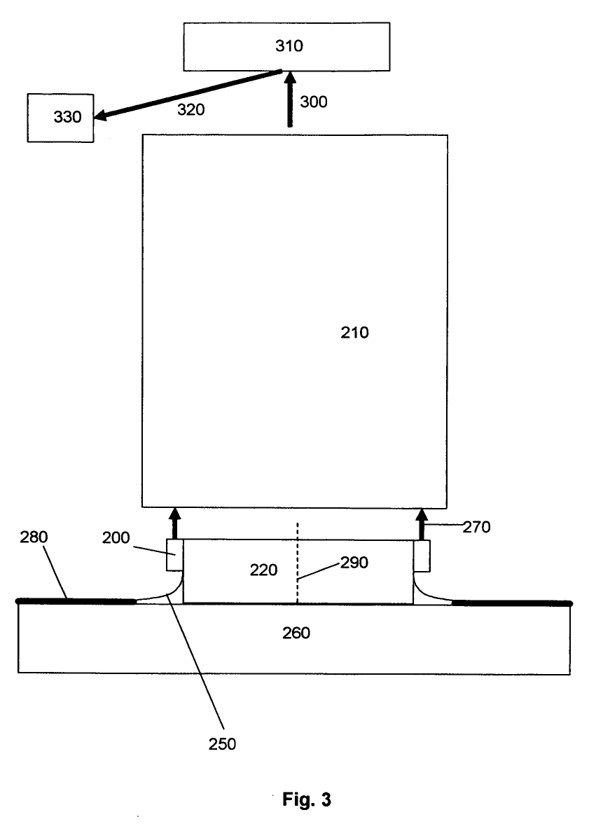

FIGS. 2 and 3 represent two views of a preferred embodiment of the present invention. FIG. 2 is an end view of a preferred embodiment of the present invention. The view of FIG. 2 is looking from the inside of a multi-mode optical fiber core 210 at a plurality of edge-emitting semiconductor lasers 200 arranged around the perimeter of a circular cross-section sub-mount 220, fitting within the core of the multi-mode optical fiber 210. The optical fiber could also be replaced by a lightpipe in some applications. Each of the plurality of lasers 200 employs a unique semiconductor gain medium composition with a unique gain peak wavelength. For example, the gain media could be quantum well regions with various compositions of InGaAsP, having gain peak wavelengths in the 1200-2100 nm range. The gain regions can be composed of any semiconductor known to provide optical gain for laser radiation. The use of a plurality of gain medium compositions overcomes the gain-bandwidth limitations of a single semiconductor gain medium, and enables the wide wavelength coverage required for spectroscopic applications. The plurality of semiconductor lasers 200 emits a plurality of radiation components 270 having a plurality of wavelengths into the fiber core 210 directly with no intervening optics. That is, the semiconductor lasers 200 are directly coupled to the optical fiber core 210. Throughout this specification, the phrase “directly coupled” refers to coupling with no intervening optical components. The numerical aperture of the fiber with core 210 is typically in the range of about 0.35 to about 0.5, enabling >50% coupling efficiency of edge-emitting semiconductor lasers with direct coupling. FIG. 2 shows typical dimensions of this arrangement, wherein each edge-emitting semiconductor laser has a width around 250 microns and a thickness around 75 microns, enabling 14 such sources to be placed around the perimeter of the 1.15 mm diameter sub-mount 220. This enables the plurality of radiation components 270 to fit within the core of a 1.5 mm multimode fiber. Typical fiber core diameters for multi-mode sensor applications are in the range of about 100 microns to about 5 millimeters.

FIG. 3 is a view of the section A-A′ indicated in FIG. 2, illustrating how the semiconductor lasers 200 can be connected to a circuit board 260, which in turn is connected to an external power supply through electrical connections 280. The connection between sources 200 and the circuit board 260 requires a 90 degree electrical bend, accomplished by a flex circuit 250, which is well-known to those skilled in the art. The electrical signals traveling along the connections 280 are in a plane substantially perpendicular to an axis 290 of the cylindrical submount 220. FIG. 3 also shows how an output radiation 300 from the fiber core 210 impinges on a sample 310, generating a diffusely reflected radiation 320 detected by an optical detector 330.

The components of FIGS. 2 and 3 function together as key elements of a compact semiconductor laser-based spectrometer. By electrically switching a power supply external to the circuit board 260, amongst the electrical connections 280 to the lasers 200, only one of the lasers is emitting radiation at any given time, and selecting the laser selects the wavelength. Further wavelength tuning can be achieved by temperature control of the submount 220, using a thermo-electric cooler, or by resistive heaters integrated with each laser 200. The preferred embodiment of this invention uses Fabry-Perot edge-emitting lasers for the lasers 200, because thermal tuning rate of lasing wavelength in such lasers is equal to the thermal tuning rate of the gain peak, which can be in the range of about 0.4 nm/C around 980 nm. This thermal tuning rate is much greater than the thermal tuning rate of grating based lasers such as DFB/DBR lasers, which tune at about 0.08 nm/C around 980 nm, or at a rate proportional to the thermal tuning rate of the material index of refraction. For example, in the 650-1000 nm range, approximately 12 Fabry-Perot semiconductor lasers arranged around the perimeter of a nearly circular cross-section polygon can, in conjunction with thermal tuning, provide complete wavelength coverage of the 650-1000 nm range. An important application of this wavelength range is in broadband diffuse optical spectroscopy for detection of water, lipids, oxy-hemoglobin, and deoxy-hemoglobin, in the detection, characterization, and therapeutic monitoring of breast cancer. This application is one example of an in-vivo biological measurement, and is discussed in (B. Tromberg, N. Shah, R. Lanning, A. Cerussi, J. Espinoza, T. Pham, L. Svaasand, and J. Butler, “Non-Invasive In Vivo Characterization of Breast Tumors Using Photon Migration Spectroscopy,” Neoplasia, vol. 2, nos. 1-2, January-April 2000, pp. 26-40). This application requires both steady state and frequency domain measurements of diffuse tissue reflectance, and the embodiment of FIGS. 2 and 3 addresses this need. Frequency domain measurements can be accomplished by applying a modulated drive current to each of the lasers 200. The embodiment of FIGS. 2 and 3 could also be used to characterize biological samples ex vivo. For this and many other applications, the spectral width of Fabry-Perot lasers, which is on the order of 1-5 nm, is adequately narrow to enable high sensitivity detection, and the <0.1 nm linewidth of grating-based semiconductor lasers such as DFB/DBR lasers is not required. Other applications may require high wavelength resolution, but not complete wavelength coverage, and the configuration of FIGS. 2 and 3 can be realized with DFB/DBR lasers to address such applications. Both DFB/DBR lasers and Fabry-Perot lasers can be modulated at high speeds, as required for frequency domain measurements of breast tissue. This modulation range is typically in the range of about 100 Mhz to about 3 Ghz.

Although the configuration of FIGS. 2 and 3 employs a circular cross-section cylinder, it is evident that the cross-section can be a polygon of any shape, such as a square, or a many-sided polygon with 4-16 facets. (Throughout this specification, we assume that the term polygon includes circles.) This is especially true when uniform modal excitation is not critical, as is the case of broadband diffuse optical spectroscopy in the 650-1000 nm range.

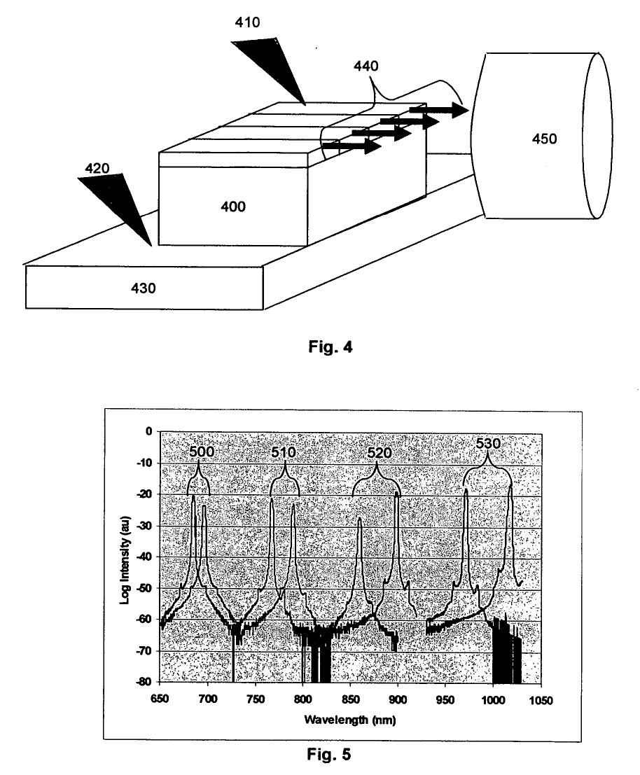

Another preferred embodiment of this invention, when the number of wavelengths is small, is a linear array. For example, in a 4-channel system, a linear array of four edge-emitting lasers with a width of 250 microns each can fit within the 1 mm core of a multi-mode fiber. Linear arrays can also be stacked to make two-dimensional arrays which can be directly coupled to fiber. FIG. 4 shows the preferred linear array embodiment, along with an experimental configuration used to test a prototype 4-channel array. In this experiment, a four element edge-emitting laser array 400, having an element to element spacing of 250 microns was fabricated and tested. A first element of this array employed an AlInGaP quantum well gain region emitting around 680 nm, a second element employed an AlGaAs quantum well gain region emitting around 780 nm, a third element employed a GaAs quantum well gain region emitting around 880 nm, and a fourth element employed an InGaAs quantum well gain region emitting around 980 nm. The array 400 was assembled from four individually processed laser die using a manual pick and place tool. Linear arrays employing a plurality of gain regions could also be assembled monolithically on a wafer scale, using wafer bonding techniques such as that described in (J. Geske, D. Leonard, M. H. MacDougal, B. Barnes, and J. E. Bowers, “CWDM Vertical Cavity Surface-Emitting Laser Array Spanning 140 nm of the C, S, and L Fiber Transmission Bands,” IEEE Photonics Technology Letters, vol. 16, no. 5, May 2004) Current was applied to each element of the array 400 through a positive electrode 410 and a negative electrode 420. The array emitted four radiation components 440 having four wavelength bands into a common multi-mode fiber 450 having a core diameter of 1 mm. The fiber was held in a fixed position as the array elements were probed sequentially, and the spectra from each element of the array was measured during thermal tuning. FIG. 5 illustrates the spectra observed from the four channels at the fiber output. The four elements of the array emit radiation in first, second, third and fourth wavelength bands 500, 510, 520, and 530, respectively, in the 650-1000 nm wavelength range, representing a total wavelength coverage of about 120 nm. FIGS. 4 and 5 represent reduction to practice of the present invention for the specific case of a linear array of four lasers directly coupled to one common multi-mode fiber, in the 650-1000 nm wavelength range.

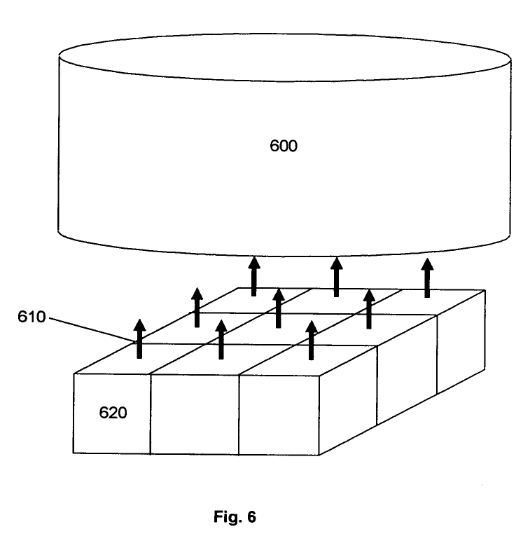

FIG. 6 illustrates another preferred embodiment of the present invention. Here a plurality of vertical cavity surface emitting lasers 620 emits a plurality of radiation components 610 directly into multi-mode fiber core 600, with no intervening optics. Each of the vertical cavity surface-emitting lasers 600 employs a gain medium of a different composition and emits at a different wavelength. Similarly to FIGS. 2 and 3, electrical switching amongst the plurality of VCSELs 600 enables coverage of a wide range of wavelengths. This is in contrast to the directly coupled VCSEL array described in (S. Y. Hu, J. Ko, E. R. Hegblom, and L. A. Coldren, “Multimode WDM Optical Data Links with Monolithically Integrated Multiple Channel VCSEL and Photo-Detector Arrays,” IEEE J Quantum Electron. vol. 34, pp. 1403-1414, 1998), where all vertical cavity surface emitting lasers employ the same gain medium material composition.

VCSELs enable easy configuration as two-dimensional arrays, and therefore a large number of VCSELs can be incorporated in the configuration of FIG. 6. However, VCSELs generally provide less output power than edge-emitting lasers, and do not work well at certain critical wavelengths. Also, all VCSELs are DBR lasers whose wavelength tunes as the material refractive index, rather than as the gain peak, so thermal tuning rates are much lower than for Fabry-Perot edge emitting lasers. The configuration of FIG. 6 serves those applications where a large number of discrete selected wavelengths is required, and where lower output power can be tolerated. Of course, further embodiments of this invention could be constructed by combining features of FIGS. 2-6, and employing both VCSELs and edge-emitters in one tunable source.

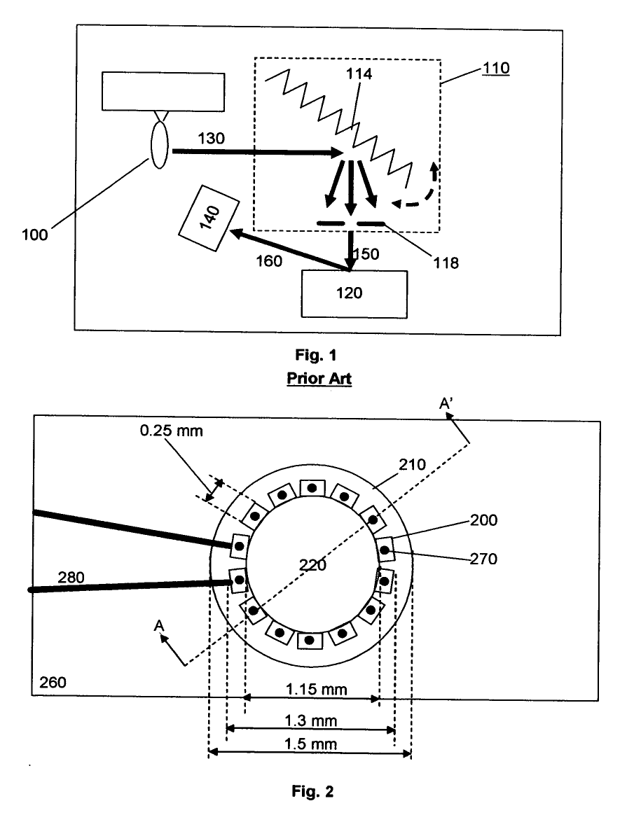

In addition to the 650-1000 nm wavelength range, other ranges and applications of interest for all embodiments of the present invention include the 800-1700 nm range for agricultural applications, and the 1100-2500 nm range for near-infrared spectroscopy. The 800-1700 nm range has proved useful in the spectroscopy of wheat, corn, and insects. See, for example (T. C. Pearson, D. T. Wicklow, E. B. Maghirang, F.Xie, and F. E. Dowell, “Detecting Aflatoxin in Single Corn Kernels by Transmittance and Reflectance Spectroscopy,” American Society of Agricultural Engineers vol. 44(5), pp. 1247-1254, 2001). The 1100-2500 nm range is extensively used in the characterization of pharmaceutical products, and is a standard wavelength range for near infrared spectroscopy. Both of the above applications rely extensively on prior art grating-based spectrometers such as those of FIG. 1, or variants thereof The present invention promises more compact instrumentation, greater signal to noise ratio, lower power dissipation, and faster measurement times. In addition, the entire wavelength range from about 650 nm to about 2500 nm can be accessed with relatively mature semiconductor laser technology, making the approach feasible. The above application areas are only intended as examples, and are not intended to be limiting. The present invention can be applied wherever spectroscopy provides useful information, using edge-emitting semiconductor lasers of any available wavelength.

While this invention has been particularly shown and described with references to preferred and alternate embodiments thereof, it will be understood by those skilled in the art that various changes in form and details may be made therein without departing from the spirit and scope of the invention as defined by the appended claims.

What is claimed is:

1. A tunable radiation source comprising
a plurality of semiconductor lasers comprising a plurality of semiconductor gain medium compositions, operative to emit a plurality of radiation components having a plurality of wavelengths
wherein each of said plurality of radiation components is directly coupled into one common multi-mode optical fiber with no optical components disposed between said plurality of semiconductor lasers and said multi-mode optical fiber,
and
means for directing electrical power to each one of said plurality of semiconductor lasers.

2. The tunable radiation source of claim 1, wherein said plurality of semiconductor lasers is a plurality of vertical cavity surface emitting lasers.

3. The tunable radiation source of claim 2, wherein said plurality of vertical cavity surface-emitting lasers is configured in a 2-dimensional array.

4. The tunable radiation source of claim 1, wherein said plurality of semiconductor lasers is a plurality of edge-emitting semiconductor lasers.

5. The tunable radiation source of claim 4, wherein said plurality of edge-emitting semiconductor lasers is a plurality of Fabry-Perot lasers.

6. The tunable radiation source of claim 4, wherein said plurality of edge-emitting semiconductor lasers is a plurality of grating-based semiconductor lasers.

7. The tunable radiation source of claim 4, wherein said plurality of edge-emitting semiconductor lasers encompasses between about 4 and about 16 edge-emitting semiconductor lasers.

8. The tunable radiation source of claim 1, further comprising means for thermally tuning at least one of said plurality of semiconductor lasers, thereby tuning at least one of said plurality of wavelengths.

9. The tunable radiation source of claim 5, further comprising means for thermally tuning at least one of said plurality of Fabry-Perot lasers, thereby tuning at least one of said plurality of wavelengths.

10. The tunable radiation source of claim 4, wherein said plurality of edge-emitting semiconductor lasers is arranged in a linear array.

11. The tunable radiation source of claim 4, wherein said plurality of edge-emitting semiconductor lasers is arranged in a 2-dimensional array.

12. The tunable radiation source of claim 1, wherein said multi-mode optical fiber has a core diameter in a range between about 100 microns and about 5 millimeters.

13. The tunable radiation source of claim 1, wherein said plurality of wavelengths is in a range between about 650 nm and about 1000 nm.

14. The tunable radiation source of claim 1, wherein said plurality of wavelengths is in a range between about 1100 nm and about 2500 nm.

15. The tunable radiation source of claim 1, wherein said plurality of wavelengths is in the range between about 800 nm and about 1700 nm.

16. The tunable radiation source of claim 9, wherein said plurality of wavelengths encompasses complete wavelength coverage over a range of at least about 200 nm.

17. The tunable radiation source of claim 1, further comprising means for electrically modulating at least one of said plurality of semiconductor lasers at frequencies in the range of about 100 Mhz to about 3 Ghz.

18. The tunable radiation source of claim 4, wherein said plurality of edge-emitting semiconductor lasers is arranged around the perimeter of a cylindrical sub-mount, wherein a cross-section of said cylindrical sub-mount is a polygon.

19. The tunable radiation source of claim 18, wherein said polygon has between about 4 and about 16 sides.

20. The tunable radiation source of claim 18, wherein said polygon is a circle.

21. The tunable radiation source of claim 18, further comprising a means for bending a path of said electrical power into a plane substantially perpendicular to an axis of said cylindrical submount.

22. The tunable radiation source of claim 21, wherein said means for bending a path of said electrical power is a flex circuit.

23. A spectrometer comprising the tunable source of claim 1, means for presenting an output radiation of said multi-mode fiber to a sample, and means for detecting at least one of a radiation reflected from said sample and a radiation transmitted through said sample.

24. The spectrometer of claim 23, wherein said sample is an in-vivo biological sample.

25. The spectrometer of claim 23, wherein said sample is an ex-vivo biological sample.

26. The spectrometer of claim 23, wherein said sample is an agricultural sample.

27. The spectrometer of claim 23, wherein said sample is a pharmaceutical sample.

28. A system for at least one of the detection, characterization, and therapeutic monitoring of breast cancer, the system comprising the tunable source of claim 1, a means for presenting an output radiation of said multi-mode fiber to in-vivo human breast tissue, and a means for detecting at least one of a radiation reflected from said breast tissue and a radiation transmitted through said breast tissue.

29. A system for at least one of the detection, characterization, and therapeutic monitoring of breast cancer, the system comprising the tunable source of claim 17, a means for presenting an output radiation of said multi-mode fiber to in-vivo human breast tissue, and a means for detecting at least one of a radiation reflected from said sample and a radiation transmitted through said sample.

30. The system of claim 28, wherein said plurality of wavelengths is in a range of about 650 nm to about 1000 nm.

31. The system of claim 29, wherein said plurality of wavelengths is in a range of about 650 nm to about 1000 nm.

32. The system of claim 28, wherein said plurality of wavelengths covers substantially all of a range from about 650 nm to about 1000 nm.

33. The system of claim 29, wherein said plurality of wavelengths covers substantially all of a range from about 650 nm to about 1000 nm.
